(19) United States
(12) Patent Application Publication
(10) Pub. No.: US 2022/0006044 A1
(43) Pub. Date: Jan. 6, 2022

(54) OPTICAL ADHESIVE AND DISPLAY PANEL

(71) Applicant: WUHAN CHINA STAR OPTOELECTRONICS SEMICONDUCTOR DISPLAY TECHNOLOGY CO., LTD., Wuhan, Hubei (CN)

(72) Inventor: Guochun YAN, Wuhan (CN)

(21) Appl. No.: 16/488,021

(22) PCT Filed: Mar. 12, 2019
(86) PCT No.: PCT/CN2019/077875

§ 371 Date: Aug. 22, 2019

(30) Foreign Application Priority Data
Dec. 18, 2018 (CN) 201811547023.9

(51) Int. Cl. H01L 51/52; H01L 51/00; H01L 27/32

(52) U.S. Cl. CPC H01L 51/5246; H01L 2251/5338; H01L 27/323; H01L 51/0097

(57) ABSTRACT

An optical adhesive and a display panel having the same, the optical adhesive includes a portion corresponding to a bending region of the display panel, an elastic modulus and hardness of this portion are lower than other regions of the optical adhesive, so that the display panel has good bending properties.

### CROSS REFERENCE TO RELATED APPLICATION

This application claims the priority of International Application No. PCT/CN2019/077875, filed on 2019 Mar. 12, which claims priority to Chinese Application No. 201811547023.9 filed on 2018 Dec. 18. The entire disclosures of each of the above applications are incorporated herein by reference.

### BACKGROUND OF INVENTION

### Field of Invention

The present invention relates to the field of display technologies, and in particular, to a method for an optical adhesive and a display panel.

### Description of Prior Art

Organic light emitting diode (OLED) displays are becoming the mainstream of the display industry due to their wide viewing angles, high color gamut and low power consumption. The development of flexible and foldable OLED displays has gradually become the development goal of the industry

In development of bendable OLEDs, a cover glass on a surface of an OLED display is first replaced by cover film or cover window to ensure bending characteristics of the display. As a display screen, its surface hardness needs to reach a certain standard. In practice, the OLED display module is a combination of multiple layers of optically clear adhesive (OCA). OCA is soft, although a surface of the cover window has a hardness of 7-9H, the surface hardness of the display panel still ranges from 1-2H or even less than 1H.

How to choose OCA adhesive layer is extremely important for the bending performance of the OLED display module. A thicker OCA adhesive layer will increase the hardness of the OLED display module and is not easy to bend. A thinner OCA adhesive layer has a bad adhesiveness which will easily peel off due to the bending stress, thereby affecting quality of the display module.

### Technical Problem

The present invention provides an optical adhesive, which is provided with a first section with better hardness and a second section which is easy to bend. The present invention solves the technical problem that the optical adhesive layer of OLED display module in the prior art has poor bending performance and poor bonding performance.

### SUMMARY OF INVENTION

In order to solve the above problems, the technical solution provided by the present invention is as follows.

The invention provides an optical adhesive comprising a first section, and a second section connected to the first section;

wherein a hardness of the second section is less than a hardness of the first section, and an elastic modulus of the second section is less than an elastic modulus of the first section.

According to a preferred embodiment of the invention, the optical adhesive further comprises a third section, the third section connected to an end of the second section away from the first section.

According to a preferred embodiment of the invention, the hardness of the second section is less than a hardness of the third section, and the elastic modulus of the second section is less than an elastic modulus of the third section.

According to a preferred embodiment of the invention, the second section comprises more than one odd-numbered sub-sections, long sides of the sub-sections are parallel to edges of the first section and the third section.

According to a preferred embodiment of the invention, when the sub-sections comprises more than three odd-numbered sub-sections, an elastic modulus of the sub-section located in the middle is increased to an elastic modulus of the sub-sections located on the side, and an elastic modulus of the sub-sections adjacent to the first section and the third section is less than an elastic modulus of the first section and the third section.

According to a preferred embodiment of the invention, when the sub-sections comprises more than three odd-numbered sub-sections, the sub-sections outside the sub-sections in the middle are alternately set based on the number of their elastic modulus, wherein an elastic modulus of the sub-section located in the middle is less than a minimum elastic modulus of the other sub-sections, and the elastic modulus of the sub-sections adjacent to the first section and the third section is less than the elastic modulus of the first section and the third section.

According to a preferred embodiment of the invention, a hardness and an elastic modulus of any two sub-sections symmetrical with respect to the sub-sections located in the middle are the same.

According to a preferred embodiment of the invention, contact surfaces of the second section with the first section and the third section are bevels.

According to a preferred embodiment of the invention, contact surfaces of the second section with the first section and the third section are curved surfaces.

According to a preferred embodiment of the invention, a Young's modulus of the first section and the third section ranges from 106 Pa to 109 Pa, and a Young's modulus of the second section ranges from 104 Pa to 106 Pa.

The present invention further provides a display panel, the display panel comprising a non-bending region and a bending region connected to the non-bending region, wherein the display panel further comprises:

a plurality of functional layers; and

an optical adhesive layer disposed between two adjacent functional layers, the optical adhesive layer comprising a first section, and a second section connected to the first section, wherein a hardness of the second section is less than a hardness of the first section, and an elastic modulus of the second section is less than an elastic modulus of the first section;

wherein the second section corresponds to a position of the bending region, and the first section corresponds to a position of the non-bending region.

According to a preferred embodiment of the invention, the non-bending region comprises a first sub-plate region and a second sub-plate region, the first sub-plate region is connected to an end of the bending region, and the second sub-plate region is connected to the other end of the bending region;

wherein the optical adhesive layer further comprises a third section, the third section connected to an end of the second section away from the first section;

wherein the first section corresponds to a position of the first sub-plate region, and the third section corresponds to a position of the second sub-plate region.

According to a preferred embodiment of the invention, a width of the bending region is W, and a bending radius of the bending region is r, and the width W is less than or equal to a product of the bending radius r and π.

According to a preferred embodiment of the invention, the display panel comprises:

a first functional layer, the first functional layer is a flexible substrate;

a first optical adhesive layer disposed on a surface of the flexible substrate;

a second functional layer, the second functional layer is an organic light emitting diode (OLED) display layer disposed on a surface of the first optical adhesive layer;

a common optical adhesive layer disposed on a surface of the OLED display layer;

a third functional layer, wherein the third functional layer is a touch panel disposed on a surface of the common optical adhesive layer; and

a second optical adhesive layer disposed on the touch panel.

According to a preferred embodiment of the invention, the display panel comprises:

a first functional layer, the first functional layer is a flexible substrate;

a first optical adhesive layer disposed on a surface of the flexible substrate;

a second functional layer, the second functional layer is an organic light emitting diode (OLED) display layer disposed on a surface of the first optical adhesive layer;

a common optical adhesive layer disposed on a surface of the OLED display layer;

a third functional layer, wherein the third functional layer is a touch panel disposed on a surface of the common optical adhesive layer; and

a third optical adhesive layer disposed on the touch panel.

The present invention further provides a method of preparing an optical adhesive layer, the method comprising the steps of:

S10, defining a first region and a second region on the surface of the substrate;

S20, using a first patterned roller to prepare a first adhesive layer in the first region to form a first segment;

S30, using a second patterned roller to prepare a second adhesive layer in the second region to form a second segment;

wherein a hardness of the second adhesive layer is less than a hardness of the first adhesive layer, and an elastic modulus of the second adhesive layer is less than an elastic modulus of the first adhesive layer.

### Beneficial Effects

The present invention provides an optical adhesive and a display panel having the same, the optical adhesive includes a portion corresponding to a bending region of the display panel, the elastic modulus and hardness of this portion are lower than other regions of the optical adhesive, so that the display panel has good bending properties.

### BRIEF DESCRIPTION OF DRAWINGS

FIG. 1 is a perspective diagram of a three-dimensional structure of an optical adhesive provided by the present invention;

FIG. 2A is a cross-sectional structural diagram of an optical adhesive provided by the present invention;

FIG. 2B is a cross-sectional diagram showing another optical adhesive provided by the present invention.

FIG. 3 is a structural diagram of a multi-subsection of an optical adhesive provided by the present invention;

FIG. 4 is a flow chart of preparing an optical adhesive layer provided by the present invention.

FIG. 4A to FIG. 4C are structural diagrams showing the steps of preparing an optical adhesive provided by the present invention.

FIG. 5A is a schematic diagram showing a structure of display layers of a display panel using an optical adhesive layer provided by the present invention;

FIG. 5B is another schematic diagram showing a structure of display layers of a display panel using an optical adhesive layer provided by the present invention;

FIG. 5C is a structural diagram of a display panel using an optical adhesive layer provided by the present invention.

FIG. 6 is another structural diagram of a display panel using an optical adhesive layer provided by the present invention;

FIG. 7 is another structural diagram of a display panel using an optical adhesive layer provided by the present invention.

### DETAILED DESCRIPTION OF PREFERRED EMBODIMENTS

The present invention is directed to the technical problem that the optical adhesive layer of an OLED display module in the prior art has poor bending performance and poor bonding performance, and the present embodiments can solve the defect.

### Embodiment 1

As shown in FIG. 1, the present invention provides an optical adhesive which includes a first section 102, and a second section 101 connected to an end of the first section 102. Further, a third section 103 is disposed at an end of the second section 101 away from the first section 102.

The first section 102 and the third section 103 are formed by using a first adhesive material. The second section 101 is formed by using a second adhesive material. The optical adhesive segments formed by the first adhesive material and the second adhesive material have different hardness and elastic modulus. Further, the hardness and the elastic modulus of the second section 101 are less than the elastic modulus of the first section 102 and the elastic modulus of the third section 103.

The second section having a softer material, the first section and the third section having a harder material are provided in the optical adhesive of the present invent. When the optical adhesive is applied into a display device, the first segment and the third segment correspond to flat plate segments of the display device. The flat plate segments are not bent. The first section and the third section are harder so that they can ensure the adhesion between adjacent layers and can provide support for the non-bending sections of the display device to ensure the flatness of the display panel. The second section corresponds to a bent section of the display device, and the second section is made of a soft material to facilitate bending of the display device.

### Embodiment 2

Edge contact surfaces are formed between the second section, the first section and the third section of the optical adhesive. Because the second section, the first section and the third section have different elastic modulus and hardness, the bonding strength of the edge contact surfaces of them are weak. The second section is easily separated from the first section and the third section by the bending stress.

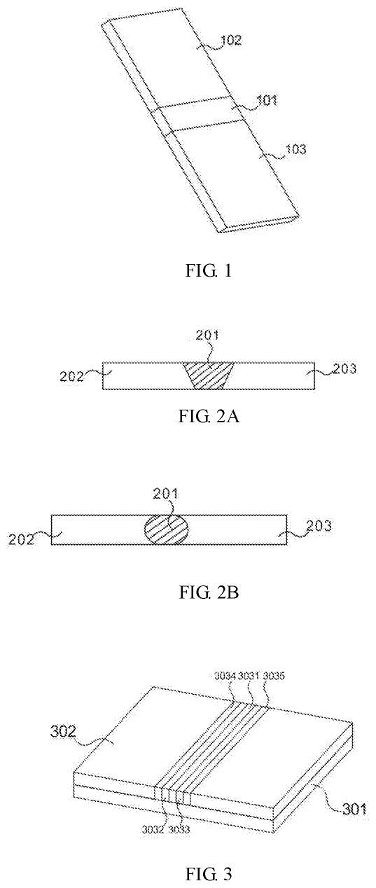

As shown in FIG. 2A, the optical adhesive includes a second section 201, a first section 202 and a third section 203 connected to two sides of the second section 201, and edge contact surfaces between the second section 201, the first section 202 and the third section 203. Wherein the edge contact surfaces are disposed in a slope such that edges of the second section 201 are interlaced with edges of the first section 202 and the third section 203. In one aspect, this arrangement increases the region of the edge contact surfaces. On the other hand, compared with the vertically disposed edge contact surfaces, the stress point of the bending stress is dispersed from the edges of the second section 201, the first section 202 and the third section 203 to the bodies of the second section 201, the first section 202 and the third section 203 when the optical adhesive is bent, thereby the possibility of separation of the edge contact faces can be reduced.

As shown in FIG. 2A, the optical adhesive includes a second section 201, a first section 202 and a third section 203 connected to two sides of the second section 201, and edge contact surfaces between the second section 201, the first section 202 and the third section 203. Wherein the edge contact surfaces are arranged in an arc such that edges of the second section 201 forms a semi-cladding structure with edges of the first section 202 and the third section 203. In one aspect, this arrangement increases the region of the edge contact surfaces. On the other hand, compared with the vertically disposed edge contact surfaces, the stress point of the bending stress is dispersed from the edges of the second section 201, the first section 202 and the third section 203 to the bodies of the second section 201, the first section 202 and the third section 203 when the optical adhesive is bent, thereby the possibility of separation of the edge contact faces can be reduced.

### Embodiment 3

The second section of the optical adhesive includes one or more odd strip subsections. Long sides of the subsections are parallel to the edges of the first section and the third section. The optical adhesive is prepared on a surface of a first substrate, a surface of the optical adhesive is prepared with a second substrate, the first substrate and the second substrate are release films. The optical adhesive further includes a first section, a second section, and a third section, the second section includes a subsection.

An elastic modulus of the first section and the second section is selected to be of the order of 10⁶ Pa to 10⁹ Pa, and an elastic modulus of the second section is selected to be of the order of 10⁴ Pa to 10⁶ Pa.

As shown in FIG. 3, the optical adhesive 302 is prepared on the surface of the first substrate 301, and the surface of the optical adhesive 302 is prepared with a second substrate, and the first substrate 301 and the second substrate are release films. The optical adhesive 302 further includes a first section, a second section, and a third section, the second section includes more than one odd subsections. The odd sub-sections are distributed along a bending direction of the display device.

The second section includes five subsections, which are a third subsection 3031 in the middle, a second subsection 3032 and a fourth subsection 3033 located on both sides of the third subsection 3031, a first subsection 3034 located on the other side of the second subsection 3032, and a fifth subsection 3035 located on the other side of the fourth subsection 3033.

For example, the distribution of elastic modulus of a plurality of the subsections can be set as: an elastic modulus of the third sub-section 3031 is increased to an elastic modulus of the sub-sections located on both sides, and an elastic modulus of the subsection adjacent to the first section and the third section is less than the elastic modulus of the first section and the third section. That is, the elastic modulus of the third sub-section 3031 is less than the elastic modulus of the second sub-section 3032 and the fourth sub-section 3033. The elastic modulus of the first sub-section 3034 is greater than the elastic modulus of the second sub-section 3032 and less than the elastic modulus of the adjacent first and third sections 302. The elastic modulus of the fifth sub-section 3035 is greater than the elastic modulus of the fourth sub-section 3033 and less than the elastic modulus of the adjacent first and third sections.

For example, the distribution of elastic modulus of a plurality of the subsections can be set as: the sub-sections outside the sub-sections in the middle are alternately set based on the number of their elastic modulus, wherein an elastic modulus of the sub-section located in the middle is less than a minimum elastic modulus of the other sub-sections, and the elastic modulus of the sub-sections adjacent to the first section and the third section is less than the elastic modulus of the first section and the third section.

In the distribution setting scheme of the above examples, any two of the subsections symmetrical with respect to the subsections located in the middle have the same hardness and modulus of elasticity to improve the bending symmetry of the display device to which the optical adhesive 302 layer is applied.

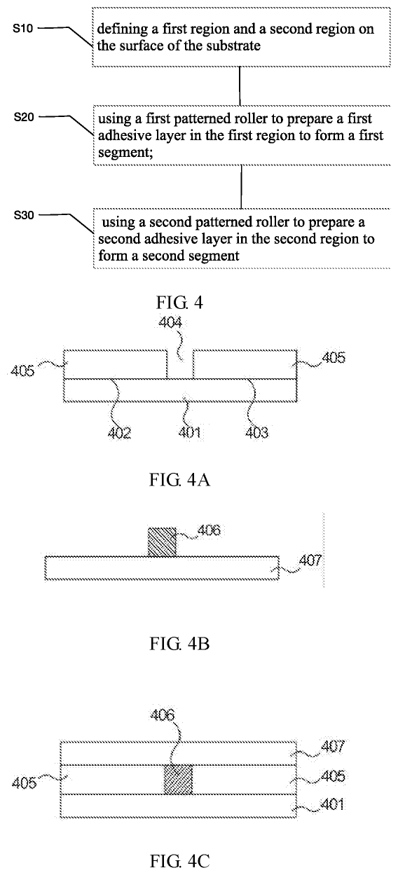

As shown in FIG. 4, the present invention further provides a method of preparing an optical adhesive layer, the method comprising the steps of:

S10, defining a first region and a second region on the surface of the substrate;

S20, using a first patterned roller to prepare a first adhesive layer in the first region to form a first segment;

S30, using a second patterned roller to prepare a second adhesive layer in the second region to form a second segment; wherein a hardness of the second adhesive layer is less than a hardness of the first adhesive layer, and an elastic modulus of the second adhesive layer is less than an elastic modulus of the first adhesive layer.

For example, when the optical adhesive is prepared, the first section and the second section can be formed by roller coating respectively. For example, a first layer is formed by coating a surface of the first substrate with a solid adhesive layer using a roller provided with a first adhesive layer pattern, a second layer is formed by coating a surface of the first substrate with a solid adhesive layer using a roller provided with a second adhesive layer pattern. The second substrate is attached to a surface of an optical adhesive formed by the second segment and the first segment.

For another example, when the optical adhesive is prepared, a first region 402 and a second region 403 are defined on a surface of the first substrate 401. The first region 402 and the second region 403 are spaced apart to form a third region 404. As shown in FIG. 4A, a first solid adhesive layer is attached to the first region 402 and the second region 403 to form the first segment 405. As shown in FIG. 4B, a second solid adhesive layer is attached to a surface of a second substrate 407 to form a bending section 406. As shown in FIG. 4C, the second substrate 407 is pasted with the first substrate 401, and the bent portion 406 is aligned to the third region 404.

In another example, when the optical adhesive is prepared, a first region and a second region are defined on the surface of the first substrate. The first region and the second region are spaced apart to form a third region. Preparing a semi-solid curing adhesive in the first region and the second region and coating a solid adhesive layer in the third region to form the second segment. Curing the semi-solid curing adhesive into a hard adhesive using ultraviolet light to form the first segment. Attaching the second substrate to the surface of the optical adhesive layer formed by the second segment and the first segment.

The semi-solid curing adhesive has a lower elastic modulus and hardness and is similar to the elastic modulus and hardness of the adhesive of the second section. When they are prepared at the same time, the difference is small and it is easy to fit each other.

In another example, when the optical adhesive is prepared, a first region and a second region are defined on the surface of the first substrate. The first region and the second region are spaced apart to form a third region. Forming a solid adhesive layer in the third region of the first substrate to form the second segment, after the optical adhesive layer is applied to the display panel, a liquid curing adhesive is dripped in the first region and the second region. Curing the liquid curing adhesive into a hard adhesive using ultraviolet light to form the first segment. Attaching the second substrate to the surface of the optical adhesive layer formed by the second segment and the first segment.

The present invent further provides a display panel, the display panel comprising a non-bending region and a bending region connected to the non-bending region, wherein the display panel further comprises: an organic light emitting diode (OLED) light emitting layer and an optical adhesive layer disposed adjacent to the OLED light emitting layer, the optical adhesive layer comprising a first section, and a second section connected to the first section, wherein a hardness of the second section is less than a hardness of the first section, and an elastic modulus of the second section is less than an elastic modulus of the first section, wherein the second section corresponds to a position of the bending region, and the first section corresponds to a position of the non-bending region.

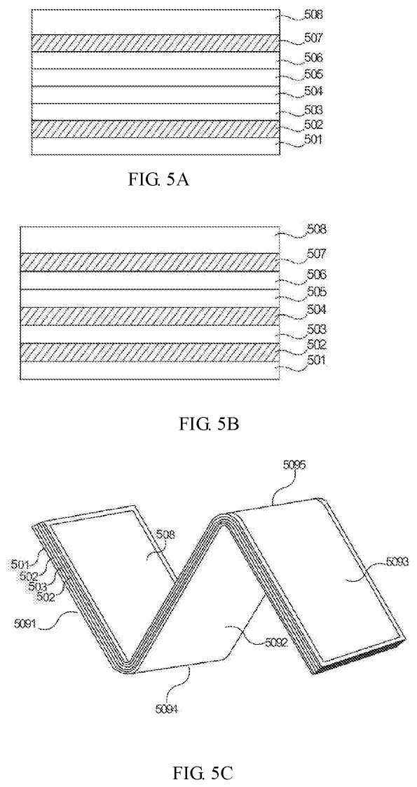

As shown in FIG. 5A, the display panel includes: a back plate 501, a first optical adhesive layer 502 prepared on a surface of the back plate 501, an OLED display layer 503 prepared on a surface of the first optical adhesive layer 502, a common optical adhesive layer 504 (having the same elastic modulus and hardness) prepared on a surface of the OLED display layer 503, a touch panel 505 prepared on a surface of the common optical adhesive layer 504, a circular polarizer 506 prepared on a surface of the touch panel 505, a second optical adhesive layer 507 prepared on a surface of the circular polarizer 506, and a cover window 508 prepared on a surface of the second optical adhesive layer 507.

As shown in FIG. 5B, the display panel includes: a back plate 501, a first optical adhesive layer 502 prepared on a surface of the back plate 501, an OLED display layer 503 prepared on a surface of the first optical adhesive layer 502, a second optical adhesive layer 507 prepared on a surface of the OLED display layer 503, a touch panel 505 prepared on a surface of the second optical adhesive layer 507, a circular polarizer 506 prepared on a surface of the touch panel 505, a second optical adhesive layer 507 prepared on a surface of the circular polarizer 506, and a cover window 508 prepared on a surface of the second optical adhesive layer 507.

As shown in FIG. 5C, the display panel to which the optical adhesive layer is applied includes a back plate 501, an OLED display layer 503 disposed on the backplane 501, a cover window 508 disposed on the OLED display layer 503, and the optical adhesive layer 502 disposed at least on both sides of the OLED display layer 503. The display device includes a first flat region 5091, a second flat region 5092, and a third flat region 5093, a first bending region 5094 connecting the first flat region 5091 and the second flat region 5092, and a second bending region 5095 connecting the second flat plate region 5092 and the third flat plate region 5093.

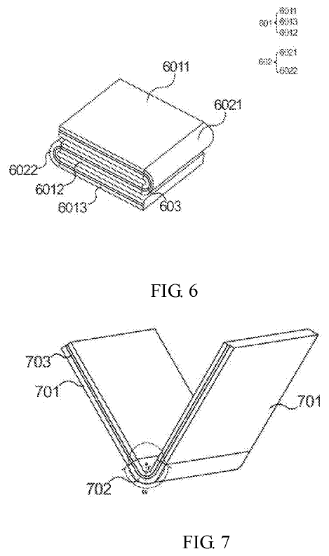

As shown in FIG. 6, the display panel is provided with the above optical adhesive layer 203. The display panel includes a flat panel region 601 and a bending region 602 located in the flat panel region. The flat panel region 601 includes a first sub-plate region 6011, a second sub-plate region 6012, and a third sub-plate region 6013. The bending region includes a first bending region 6021 and a second bending region 6022. The first sub-plate region 6011 and the second sub-plate region 6012 are connected by a first bending region 6021. The other side of the second sub-plate region 6012 is connected to a third sub-plate region 6013 through the second bending region 6022.

For example, the first sub-plate region 6011, the second sub-plate region 6012, and the third sub-plate region 6013 have a same length, and any two adjacent sub-plate regions can be folded by the bending region.

For another example, a sum of lengths of the first sub-plate region 6011 and the third sub-plate region 6013 is equal to or less than a length of the second sub-plate region 6012. The first sub-plate region 6011 is bent by the first bending region 6021 and can be attached to a surface of the second sub-plate region 6012. The third sub-plate region 6013 is bent by the second bending region 6022 and can be attached to the surface of the second sub-plate region 6012.

As shown in FIG. 7, the display panel is provided with the above optical adhesive layer 703. The display panel includes a flat panel region 701 and a bending region 702 located in the flat panel region 701. The width w of the bending region 702 is less than or equal to the product of a bending radius r of the display panel and π. The bending radius r of the display panel is a radius of a semi-circular arc formed when the display panel is folded in half, the circumference of the semi-circular arc C=πr. The width w of the bending region 702 needs to be less than or equal to the circumference C of the semi-circular arc to satisfy the bending angle of the display device.

The present invention provides an optical adhesive and a display panel having the same, the optical adhesive includes a portion corresponding to a bending region of the display panel, the elastic modulus and hardness of this portion are lower than other regions of the optical adhesive, so that the display panel has good bending properties.

As is understood by persons skilled in the art, the foregoing preferred embodiments of the present disclosure are illustrative rather than limiting of the present disclosure. It is intended that they cover various modifications and that similar arrangements be included in the spirit and scope of the present disclosure, the scope of which should be accorded the broadest interpretation so as to encompass all such modifications and similar structures.

What is claimed is:

1. An optical adhesive comprising a first section, and a second section connected to the first section;
wherein a hardness of the second section is less than a hardness of the first section, and an elastic modulus of the second section is less than an elastic modulus of the first section.

2. The optical adhesive according to claim 1, wherein the optical adhesive further comprises a third section, the third section connected to an end of the second section away from the first section.

3. The optical adhesive according to claim 2, wherein the hardness of the second section is less than a hardness of the third section, and the elastic modulus of the second section is less than an elastic modulus of the third section.

4. The optical adhesive according to claim 3, wherein the second section comprises more than one odd-numbered sub-sections, long sides of the sub-sections are parallel to edges of the first section and the third section.

5. The optical adhesive according to claim 4, wherein when the sub-sections comprises more than three odd-numbered sub-sections, an elastic modulus of the sub-section located in the middle is increased to an elastic modulus of the sub-sections located on the side, and an elastic modulus of the sub-sections adjacent to the first section and the third section is less than an elastic modulus of the first section and the third section.

6. The optical adhesive according to claim 4, wherein when the sub-sections comprises more than three odd-numbered sub-sections, the sub-sections outside the sub-sections in the middle are alternately set based on the number of their elastic modulus, wherein an elastic modulus of the sub-section located in the middle is less than a minimum elastic modulus of the other sub-sections, and the elastic modulus of the sub-sections adjacent to the first section and the third section is less than the elastic modulus of the first section and the third section.

7. The optical adhesive according to claim 5, wherein a hardness and an elastic modulus of any two sub-sections symmetrical with respect to the sub-sections located in the middle are the same.

8. The optical adhesive according to claim 1 wherein contact surfaces of the second section with the first section and the third section are bevels.

9. The optical adhesive according to claim 1, wherein contact surfaces of the second section with the first section and the third section are curved surfaces.

10. The optical adhesive according to claim 2, wherein a Young's modulus of the first section and the third section ranges from 106 Pa to 109 Pa, and a Young's modulus of the second section ranges from 104 Pa to 106 Pa.

11. A display panel, the display panel comprising a non-bending region and a bending region connected to the non-bending region, wherein the display panel further comprises:
a plurality of functional layers; and
an optical adhesive layer disposed between two adjacent functional layers, the optical adhesive layer comprising a first section, and a second section connected to the first section, wherein a hardness of the second section is less than a hardness of the first section, and an elastic modulus of the second section is less than an elastic modulus of the first section;
wherein the second section corresponds to a position of the bending region, and the first section corresponds to a position of the non-bending region.

12. The display panel according to claim 11, wherein the non-bending region comprises a first sub-plate region and a second sub-plate region, the first sub-plate region is connected to an end of the bending region, and the second sub-plate region is connected to the other end of the bending region;
wherein the optical adhesive layer further comprises a third section, the third section connected to an end of the second section away from the first section;
wherein the first section corresponds to a position of the first sub-plate region, and the third section corresponds to a position of the second sub-plate region.

13. The display device according to claim 11, wherein a width of the bending region is W, and a bending radius of the bending region is r, and the width W is less than or equal to a product of the bending radius r and π.

14. The display panel according to claim 11, wherein the display panel comprises:
a first functional layer, the first functional layer is a flexible substrate;
a first optical adhesive layer disposed on a surface of the flexible substrate;
a second functional layer, the second functional layer is an organic light emitting diode (OLED) display layer disposed on a surface of the first optical adhesive layer;
a common optical adhesive layer disposed on a surface of the OLED display layer;
a third functional layer, wherein the third functional layer is a touch panel disposed on a surface of the common optical adhesive layer; and
a second optical adhesive layer disposed on the touch panel.

15. The display panel according to claim 11, wherein the display panel comprises:
a first functional layer, the first functional layer is a flexible substrate;
a first optical adhesive layer disposed on a surface of the flexible substrate;
a second functional layer, the second functional layer is an organic light emitting diode (OLED) display layer disposed on a surface of the first optical adhesive layer;
a common optical adhesive layer disposed on a surface of the OLED display layer;
a third functional layer, wherein the third functional layer is a touch panel disposed on a surface of the common optical adhesive layer; and
a third optical adhesive layer disposed on the touch panel.
